(19) United States
(12) Patent Application Publication
(10) Pub. No.: US 2026/0072359 A1
(43) Pub. Date: Mar. 12, 2026

(54) SYSTEM AND METHOD FOR LIBRARY CONSTRUCTION AND USE IN MEASUREMENTS ON PATTERNED STRUCTURES

(71) Applicant: NOVA LTD., Rehovot (IL)

(72) Inventors: Zvi Gorohovsky, Rehovot (IL); Daphna Peimer, Rehovot (IL); Amit GODEL, Kiryat Ono (IL); Jacob Ofek, Rehovot (IL); Yotam CAMUS, Rishon Lezion (IL); Lilach TAMAM, Rehovot (IL)

(73) Assignee: NOVA LTD., Rehovot (IL)

(21) Appl. No.: 18/872,265

(22) PCT Filed: Dec. 14, 2022
(86) PCT No.: PCT/IL2022/051328

§ 371 Date: Dec. 5, 2024

(30) Foreign Application Priority Data
Jun. 6, 2022 (IL) 293633

(51) Int. Cl. G03F 7/00; G06T 7/00; G06T 7/60

(52) U.S. Cl. CPC G03F 7/70625; G06T 7/0004; G06T 7/60; G06T 2207/20084

(57) ABSTRACT

A computer system is presented configured and operable as a library constructor for use in extracting one or more parameters of a patterned structure from real time measured data obtained on said structure. The system comprises: data input utility for receiving input data comprising preliminary measured data obtained from at least a part of a structure, and comprising data indicative of user-defined quality of measurement results (QOR); and a data processor.

### TECHNOLOGICAL FIELD

The invention is in the field of automatic model-based measurements of parameters of patterned structures, and relates to construction and use of library for interpreting measured data, which is particularly useful in semiconductor industry, e.g., for the control of a manufacturing process.

### BACKGROUND

It is a common goal of various stages in the semiconductor industry to characterize the properties of a semiconductor structure. To this end and keeping in mind reduction of the dimensions of semiconductor devices based on such structures, highly sensitive metrology tools and accurate data analysis are required for monitoring the properties of the semiconductor structure.

Optical Critical Dimension (OCD) measurement technique (known also as Scatterometry) is known as being efficient for measuring parameters of patterned (periodic) structures. Measured data is typically optical data, which can be analyzed to derive information regarding the geometrical parameters of patterns including thicknesses, critical dimension (CD), line spacing, line width, wall depth, wall profile, etc., as well as optical constants of materials included in the sample. Optical metrology tools used for such measurements are typically ellipsometry and/or reflectometry-based tools. Reflectometry based tools typically measure changes in the magnitude of radiation returned/transmitted from/through the sample, and ellipsometry based tools typically measure changes of the polarization state of radiation after interacting with the sample. In addition, or as alternative to these techniques, angular analysis of light returned (reflected and/or scattered) from a patterned (periodic) structure could be used to measure the parameters that define/characterize the structure.

Data analysis is typically performed using a fitting procedure based on theoretical model-based data and/or reference data, and the structure parameters are derived from the theoretical data satisfying the “best fit” condition with the measured data. More specifically, this approach for measured data interpretation generally includes comparison between the theoretical and measured data. Theoretical data is based on one or more optical models, each based on various combinations of multiple parameters. The parameters taken into account in the model are typically of two types, one associated with the structure and the other associated with the measurement technique. If the comparison stage does not provide a desired result, model parameters of the theoretical data are varied, thus varying the theoretical input data, and comparison is repeated until desired degree of fit (e.g., convergence to minimal value of a merit function) is obtained.

### General Description

There is a need in the art for a novel approach for measured data interpretation allowing data analysis optimization to meet the specific (customized) requirements of process control application.

As described above, theoretical data (including various models or multiple parameters sets of a certain model), is typically provided for a structure of a specific type (having certain geometrical and material characteristics). This theoretical data is typically generated off-line, i.e., prior to and independent of the actual measurements on a specific structure and presents a collection (library) of theoretical signals (signatures) each corresponding to data measurable from a certain type of structure under certain measurement conditions (i.e., values of parameters). In case of spectrometry-based OCD measurements in patterned structures, such as semiconductor wafers, these may be spectral signatures.

Most semiconductor process control applications operate at a lot level, where wafers of the lot are sequentially measured between process steps. As the geometries shrink and the performance and chip densities continue to increase, control of various manufacturing processes need finer levels of control and monitoring, such as wafer-to-wafer (W2W), within-wafer (WIW) and die-to-die variation of one or more critical parameters (e.g., pattern features).

Process control in high end applications presents new challenges. In particular, stabilization of the manufacturing process and yield optimization require tight process control and highly accurate OCD metrology. Among the important process parameters requiring tight control are: repeatability, correlation to reference, tool-to-tool (T2T) variation in measurement, radial trend, de-correlation of parameters, site/layer-to-site/layer matching, DOE any others. On the one hand, the final measurement accuracy of the library search, which is one of the most commonly used methods for solving the inverse problem in optical scatterometry, is highly dependent on the grid interval selected for each parameter in the library. The time cost of the parameter extraction increases dramatically when the grid interval is decreasing.

The present invention provides a novel technique for creating an optimized library, e.g., for scatterometry-based theoretical data. Such optimized library, on the one hand, meets the basic requirement that, for any measured spectrum, it returns parameter values and a theoretical spectrum, so best fit can be one of the criteria used to determine the results, and, on the other hand, it has internal degrees of freedom (is flexible) such that the quality of results for the available measured data can be used in addition to (or instead of) best fit to obtain the best interpretation scheme. This library optimization procedure is performed off-line, and upon creating the optimized library (after optimization on available data), it can be used to interpret new measured spectra.

The technique of the present invention eliminates a need for manual trial and error optimizations, e.g., of library matching, which is critical for very tight time frame during production processes and enables a novel automatic and robust interpretation flows to aid in achieving an accurate solution.

According to one broad aspect of the invention, there is provided a computer system configured and operable as a library constructor for use in extracting one or more parameters of a patterned structure from real time measured data obtained on said structure, the computer system comprising:
data input utility for receiving input data comprising preliminary measured data obtained from at least a part of a structure, and comprising data indicative of user-defined quality of measurement results (QOR); and
a data processor configured and operable for processing and analyzing the input data and predetermined theoretical modeled data corresponding to said measured data to modify said theoretical modeled data and defining optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured.

In some embodiments, the data processor comprises a library optimizer utility configured and operable to provide the theoretical modeled data satisfying the first condition and apply a modification procedure to these theoretical modeled data by iterative training and testing it on the preliminary measured data in accordance with one or more merits determined by the data indicative of the user-defined QOR, until the one or more merits satisfy a predetermined ranking, to thereby obtain the optimized theoretical data.

In some embodiments, the library optimizer utilizes previously prepared and stored initial theoretical modeled data satisfying the first condition. In some other embodiments, the library optimizer utility may be configured to generate the theoretical modeled data satisfying the first condition. To this end, the library optimizer may operate to applying iterative training, testing and validation procedures to at least one predetermined model using train and test parameters of the structure.

The library optimizer utility may include the following utilities/modules:
a library estimator having library convergence criteria with respect to model data;
an interpretation engine associated with said library estimator and being configured and operable to interpret input measured data and operate together with said library estimator to perform iterative data interpretation to provide interpretation results enabling to identify theoretical modeled data matching said input measured data, wherein said interpretation engine has internal degrees of freedom for modifying the interpretation results by interpreting both the preliminary measured data and the QOR, enabling to determine a theoretical data set formed by matching theoretical data and corresponding theoretical values for a set of structure parameters;
a merits evaluator utility configured and operable to analyze a quality of results represented by said set of parameters with respect to said QOR and generate data indicative of corresponding at least one merit;
a ranking utility configured and operable to rank said data indicative of the at least one merit and, upon identifying that the rank does not satisfy said second condition, initiate operation of the interpretation engine and the library estimator with modified library convergence criteria to perform the iterative data interpretation procedure by modifying the theoretical matching data until it satisfies the second condition.

Considering measurements on patterned structures progressing on a production line (such as semiconductor wafers), the data indicative of the user-defined QOR may include one or more of the following: repeatability of measurement for at least one parameter; correlation of at least one parameter of the structure to reference, tool-to-tool (T2T) variation in measurement, radial trend, de-correlation of parameters, site/layer-to-site/layer matching, Design-of-experiment (DOE).

The library optimizer utility is configured to generate the theoretical modeled data satisfying the first condition by applying iterative training, testing and validation procedures to at least one predetermined model using train and test parameters of the structure.

In some embodiments, the library optimizer utility comprises:
a library estimator having library convergence criteria with respect to model data;
an interpretation engine associated with said library estimator and being configured and operable to interpret input measured data and operate together with said library estimator to perform iterative data interpretation to provide interpretation results enabling to identify theoretical modeled data matching said input measured data, wherein said interpretation engine has internal degrees of freedom for modifying the interpretation results by interpreting both the preliminary measured data and the QOR, enabling to determine a theoretical data set formed by matching theoretical data and corresponding theoretical values for a set of structure parameters;
a merits evaluator utility configured and operable to analyze a quality of results represented by said set of parameters with respect to said QOR and generate data indicative of corresponding at least one merit;
a ranking utility configured and operable to rank said data indicative of the at least one merit and, upon identifying that the rank does not satisfy said second condition, initiate operation of the interpretation engine and the library estimator with modified library convergence criteria to perform the iterative data interpretation procedure by modifying the theoretical matching data until it satisfies the second condition.

In some embodiments, the measured data is optical data. For example, the measured data comprises spectral data.

In some examples, the data indicative of the user-defined QOR comprises a degree to which the theoretical modeled data predicts at least one of geometrical and material-relating parameters of the structure, for different theoretical spectra.

In some embodiments, the data indicative of the user-defined QOR comprises degree of smoothness of at least one of geometrical and material-related parameters across the same structure or within several structures.

According to another broad aspect of the invention, it provides a data processing method for extracting one or more parameters of a patterned structure from real time measured data obtained on said structure The method comprises:
receiving input data comprising preliminary measured data obtained from at least a part of a structure, and data indicative of user-defined quality of measurement results (QOR); and
processing and analyzing the input data and predetermined theoretical modeled data corresponding to said measured data to modify said theoretical modeled data and define optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-1E show schematically a known in the art technique of library construction and use, wherein FIG. 1A shows the library training, testing and validation stages; FIG. 1B schematically shows operation of the library with its associated interpretation engine to interpret newly measured data by fitting; FIG. 1C exemplifies the principle of library construction using neural network; FIG. 1D exemplifies the principle of regression-based library construction; and FIG. 1E shows an example of self-convergence results of spectral fit during library training/testing according to the conventional approach of library construction;

FIG. 2 is a block diagram exemplifying the main principles of the invention for configuration and operation of a library constructor;

FIG. 3 is a flow diagram exemplifying a method performed by the library constructor system of the invention;

FIGS. 4A-4C illustrate the main operational steps of the library construction according to the invention, wherein FIG. 4A illustrates the operation of the library estimator together with its associated optimized interpretation engine configured according to the invention to utilize additional data relating to user-defined quality of measurement result and construct the optimized library; FIG. 4B illustrates the operation of the optimized library to interpret the real-time measure data and extract structure parameter(s); and FIG. 4C shows some examples of quality of results conditions typically required in the semiconductor industry;

FIG. 5 schematically illustrates a solution flow which would be needed to incorporate the additional user input requirements while using a library configured according to the conventional approach;

FIG. 6 is a top-level flow diagram of the approach of the invention for optimized library creation and use;

FIG. 7 exemplifies best self-convergence of the library achievable with the convention approach (two solutions) as compared to the same achievable by the optimized library according to the invention providing a better fitting model to the broader set of constraints.

### DETAILED DESCRIPTION OF EMBODIMENTS

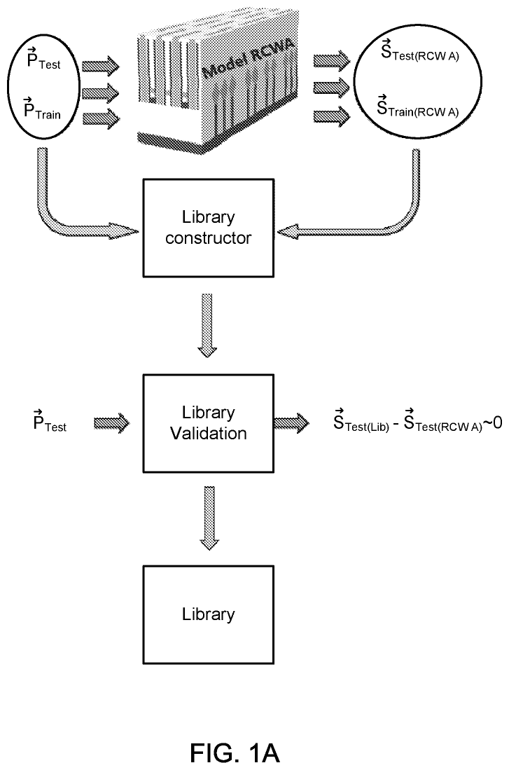

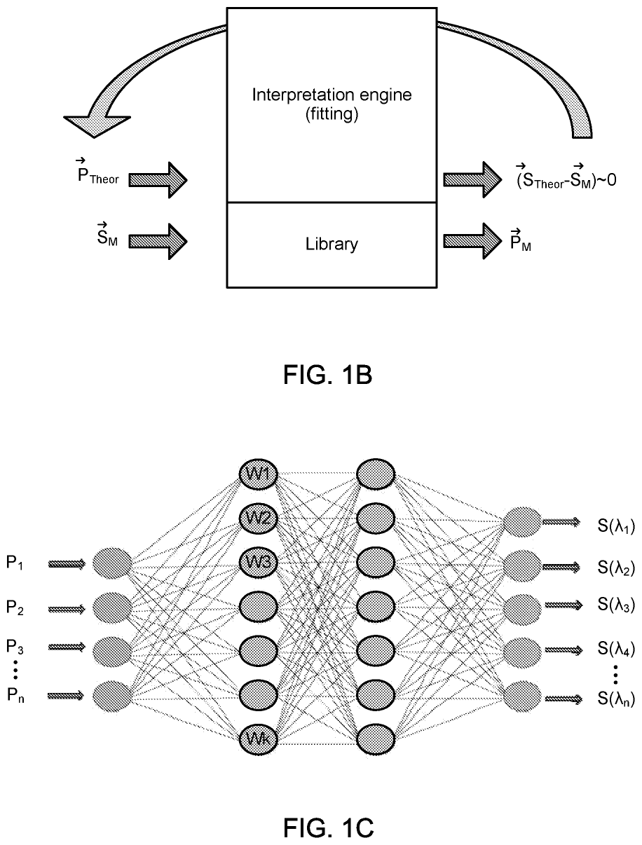

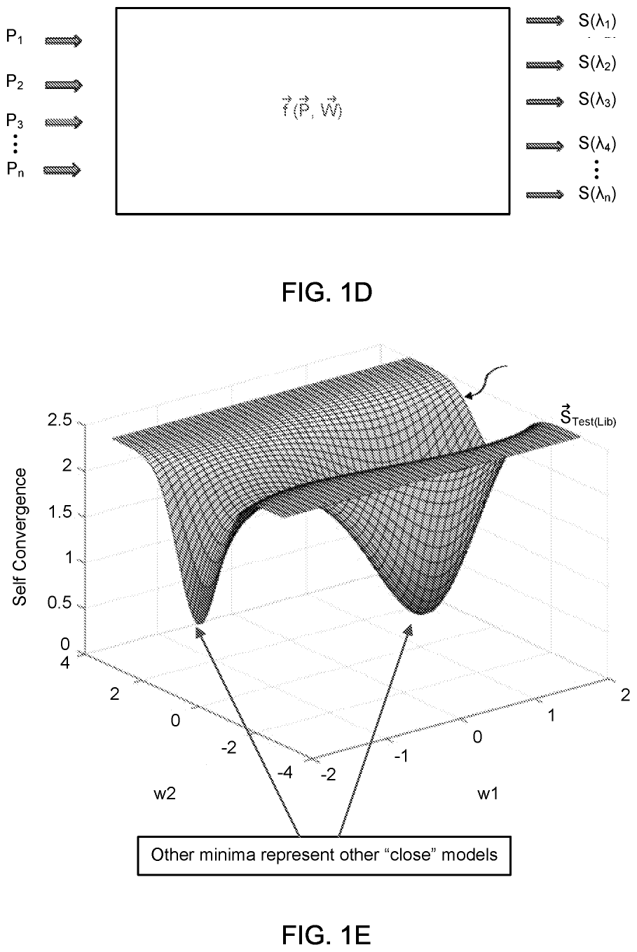

In order to better understand the principles of the present invention, reference is first made to FIGS. 1A to 1E illustrating schematically a known process to construct and use a library (theoretical model-based data, e.g., spectral data) for interpretation of measured data (e.g., spectral data) to evaluate structure parameters.

As shown in FIG. 1A, each of one or more predetermined models (e.g., RCWA) undergoes training and testing, and the resulting theoretical spectra inputs a library constructor, to be further validated to form the library data.

Each model is configured to describe detectable optical response of a structure, having predetermined general characteristics (material and geometry relating parameters), under predetermined illumination and detection conditions (measurement conditions). The model, e.g., Rigorous-Coupled-Wave-Analysis (RCWA) model, describes relation between the detectable optical response and various parameters of the structure each varying within a respective parametric space/range.

During the library construction stage, train set of parameters, \vec{P}_{Train}, is input to the model and corresponding theoretical spectra set \vec{S}_{Train(RCWA)} is obtained. These theoretical spectra thus represent the library data (multiple spectra) for the given model.

The train set of parameters, \vec{P}_{Train}, includes parameters that are relatively highly dependent on measurement conditions and/or change of one or more other parameters of the structure.

The library construction also includes application of the same model to a second parameter set, \vec{P}_{Test}, chosen randomly from the parameter range that was used in the training procedure, and respective test set of spectra, \vec{S}_{Test(RCWA)} is determined. Then, the test spectra set, \vec{S}_{Test(RCWA)}, are used in the stage of the library validation, i.e., testing that the theoretical data responds correctly to new input data, \vec{P}_{Test}, that were not used in the training.

The library responds to the new input parameter set. \vec{P}_{Test}, by the corresponding theoretical spectra. The validation stage utilizes a fitting procedure (iterative procedure) performed until the best fit theoretical spectra \vec{S}_{Test(Lib)} is obtained, i.e. upon specified error criterion is met, providing closest possible match between the theoretical spectra provided by the library data. \vec{S}_{Test(Lib)}, for the test parameter set, \vec{P}_{Test}, and the respective theoretical set of spectra, \vec{S}_{Test(RCWA)}, determined directly from the model (RCWA): \vec{S}_{Test(Lib)}−\vec{S}_{Test(RCWA)}˜0, defining the library convergence criteria. The so-constructed library presents theoretical data which mimics the given model (e.g., RCWA).

This library, together with its corresponding interpretation utility (for a given model), can then be used to interpret new measured data, e.g., spectra, to determine the parameters of investigated structures. This is illustrated schematically in FIG. 1B. As shown, the measured data, (\vec{S}_{M}), enters the library and the interpretation utility to find the theoretical spectra corresponding to the best fit condition between theoretical spectra (\vec{S}_{Theor}) of the library data and measured spectra (\vec{S}_{M}). \vec{S}_{Theor}−\vec{S}_{M}˜0, which is achieved using iterative algorithm/interpretation engine, e.g. Levenberg-Marquard, and the values of the parameters \vec{P}_{M} corresponding to the best-fit theoretical spectra are determined as the parameters of the structure being measured.

Generally, the library constructor may be any one of Neural Network, Grid estimator, simple regression, etc. FIGS. 1C and 1D exemplify in the self-explanatory manner, the principles of, respectively, the neural network and simple regression-based library construction. Prior to training, user (or software utility) defines which of the model parameters are to be floated and selects their initial values, and which parameters are to be kept fixed during the library construction process and sets for them nominal values. In addition, spectral settings/channels (wavelength selection) are fixed. The training procedure is aimed at finding the appropriate inner parameters wᵢ of a neural network or function that optimally translates each train parameters' vector P₁, . . . , Pₙ into the respective spectrum S(λ₁), . . . , S(λₙ). Once the training is initiated, the library constructor sets the inner parameters/coefficients (e.g., neuron activation weights) wᵢ. The weights wᵢ are trained to give the best library self-convergence to the closest model (mimic RCWA).

As shown in FIG. 1E, the model spectrum, \vec{S}_{Test(Lib)}, conforming (self-converging) to the minimal error criterion (condition that \vec{S}_{Test(Lib)}−\vec{S}_{Test(RCWA)}˜0) is not unique, as other minima exist as well and they represent other “close” models. Additional information is thus needed in order to select the best-fit minimum.

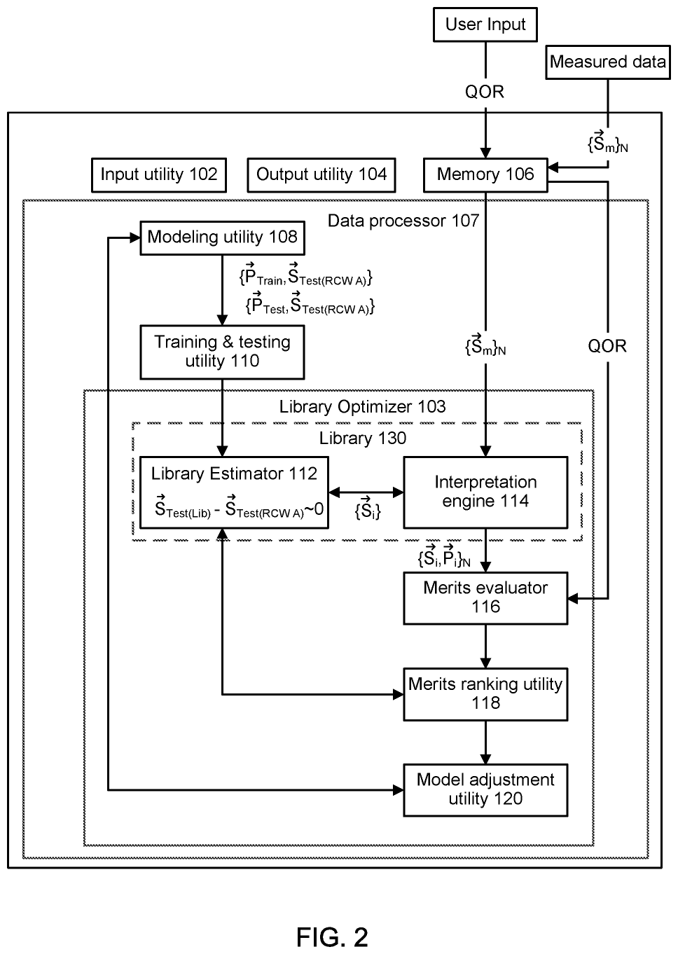

Reference is now made to FIG. 2 illustrating, by way of a block diagram, the main principles of the invention for configuration and operation of a library constructor 100 of the present invention. The library constructor 100 is configured and operable to construct a novel library 130. Such library 130 meets the basic requirement, for any measured spectrum, in that it identifies a best-fit theoretical spectrum and returns corresponding parameter values, as described above. In other words, best fit can be one of the criteria used to determine the results, however, as will be described further below, the library estimator of the present invention provides a single solution for the best fit condition. Further, the library 130 is also configured with internal degrees of freedom (flexibility) providing that the predefined degree of quality of results QOR for the measured data are used to obtain the best interpretation scheme.

Such flexibility is needed in practical process control applications, which typically require that theoretical data (library) is automatically self-adjustable to additional external data (user input) relating to predetermined conditions of the specific application, i.e., quality of results of structure inspection/measurement. Such specific conditions include one or more of the following: repeatability, correlation to reference, tool-to-tool (T2T) variation in measurement, radial trend, de-correlation of parameters, site/layer-to-site/layer matching, DOE, etc.

The library constructor 100 is configured as a computer system, including, inter alia, such main functional utilities as data input and output utilities 102 and 104, memory 106 and data processor 107. The data processor 107 includes modeling utility 108 and training & testing utility 110 which are configured as described above to utilize one or more predetermined models to train & test model data (theoretical data) \vec{S}_{Train(RCWA)} and \vec{S}_{Test(RCWA)} generated by each one of the models in association with structure parameters \vec{P}_{Train} and \vec{P}_{Test}.

A novel aspect of the present invention is in replacing a conventional library constructor by a novel library optimizer utility 103. The library optimizer is configured and operable to utilize user input including data indicative of user requirements/condition(s) for quality of results (QOR). The library optimizer 103 includes an optimized data interpretation scheme implemented by interpretation engine 114, merit evaluator 116, and merit ranking utility 118, which operate together to evaluate whether best fit theoretical data also satisfies predetermined criteria with regards to additional merit(s) defined by the quality of results (QOR) condition(s), and in case it does not, further adjust the model and re-estimate the library. To this end the library optimizer also includes model adjustment utility 120. The result of this scheme is the creation of an optimized library 130 formed by library estimator 112 and interpretation engine 114.

Thus, the library 130 is constructed offline once, for given one or more user defined quality of results condition(s) and can then be used in online mode for interpretation of real time measured data to determine the structure parameters.

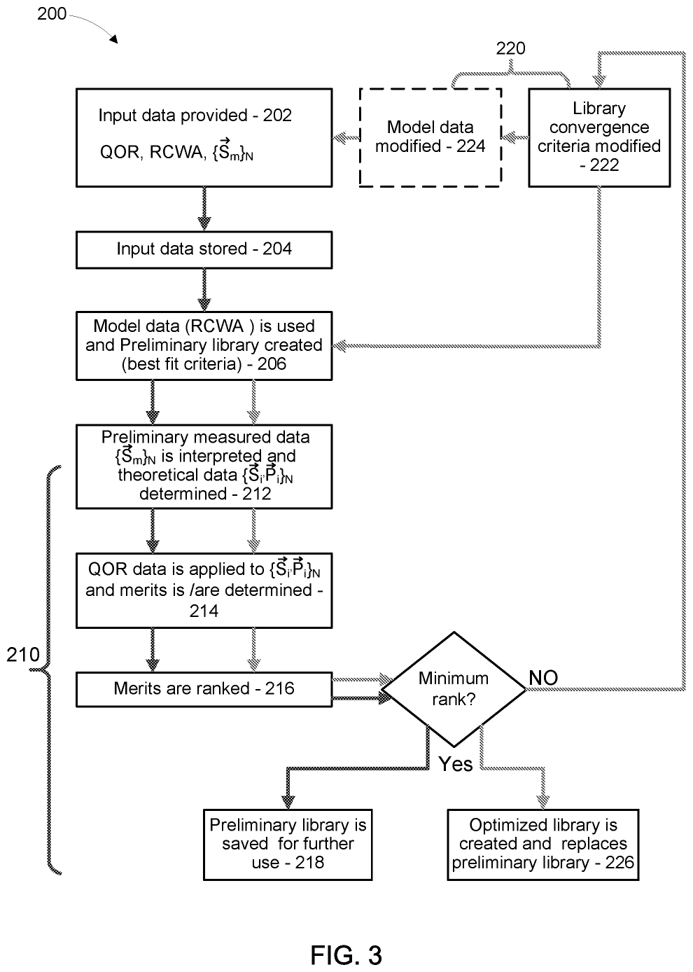

The operation of the library constructor 100 will now be described with reference to FIGS. 2 and 3 where FIG. 3 exemplifies a flow diagram 200 of the operational steps of a method performed by the system 100 of FIG. 2.

First, input data is provided (step 202). This input data includes at least one model (e.g., RCWA) suitable to describe measurements of a specific structure by a specific measurement scheme/condition, and user input with regards to quality of results QOR, as well as some preliminary provided measured data including N spectra, i.e., {\vec{S}ₘ}_{N}.

In this specific non limited example scatterometry measurements are considered and model of RCWA type is used. It should however be understood that the present invention is neither limited to any specific type of measurements as well as any specific model describing collection of measured data (i.e., any measurement scheme).

The input data is typically stored in memory 106-step 204. The model data is used by utilities 108 and 110 to generate theoretical data, \vec{S}_{Train(RCWA)} and \vec{S}_{Test(RCWA)}, in association with structure parameters \vec{P}_{Train} and \vec{P}_{Test}, in a well-known manner as also described above-step 206. This enables to perform preliminary library construction by operation of library estimator 112 and interpretation 114 using initial library convergence criteria, to meet the best fit criteria with respect to selected model, as was described above (step 206).

In addition, the optimized library estimator 103 and interpretation engine 114 are configured according to the invention to be further involved in the library construction stage to enable the library to meet QOR criteria-steps 210. Once constructed, the library 130 can be used for interpretation of newly measured data (spectra).

More specifically, the interpretation engine 114 is configured such that it has internal degrees of freedom which allows modifying/optimizing the interpretation results by interpreting additional data including QOR (user input) and the preliminary provided measured data {\vec{S}ₘ}_{N}. To this end, the interpretation engine 114 operates together with the library estimator 112 to determine the theoretical spectra corresponding to/matching with the measured data {\vec{S}ₘ}_{N} and thus determine the corresponding theoretical parameter values and {\vec{P}ᵢ}_{N}, thus forming the corresponding data set {\vec{S}ᵢ, \vec{P}ᵢ}_{N}—step 212.

The quality of results represented by the set of parameters {\vec{P}ᵢ}_{N} is evaluated by the merits evaluator 116-step 214. The merits are evaluated with respect to one or more QOR conditions. As indicated above, such QOR may be associated with one or more of the following conditions to be satisfied/met by the measurements (i.e., by interpretation of the measured data): repeatability, correlation to reference, tool-to-tool (T2T) variation in measurement, radial trend, de-correlation of parameters, site/layer-to-site/layer matching. DOE any others. Considering for example, the repeatability condition the measured data includes a plurality of measured data pieces corresponding to a plurality of measurement sites and variation of the results for structure parameters' values should be within prescribed merit.

The merits are thus calculated (as will be exemplified further below) and analyzed by merit ranking utility 118 using predetermined ranking function (e.g., summing of merits)—step 216. If the rank meets the requirement of a pre-determined threshold (typically a minimum value), the respective theoretical spectra {\vec{S}ᵢ}_{N} determined by the library data (preliminary library estimator function) satisfies the requirements for both, the best fit criteria and the QOR criteria, construction of the optimized library 130 is accomplished, and it may be saved for further use in online measurements-step 218. If, however, the merit ranking utility 118 identifies that the rank does not meet the thresholding requirement/condition (e.g., is above threshold), the model adjustment utility 120 is activated to revise the model-step 220. In this connection it should be understood that the model is typically configured allowing model data extrapolation, and this is implemented by the modeling utility 108 to provide a modified library convergence criteria (step 222) and possibly modified model data (step 224), and the entire process is repeated using this modified data until the above two major criteria are achieved, and the corresponding optimized library 130 is accomplished and replaces the preliminary library—step 226.

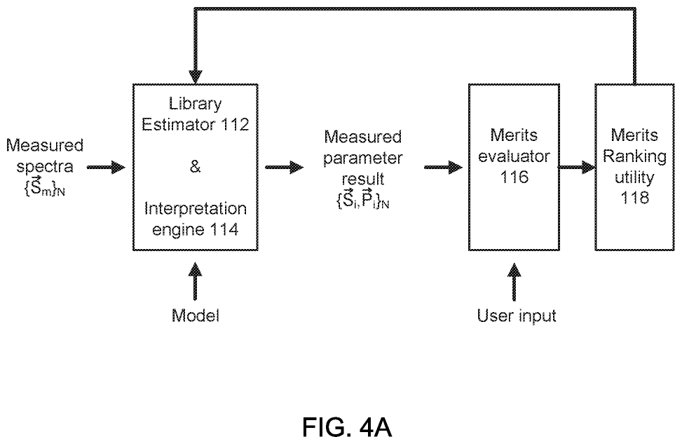

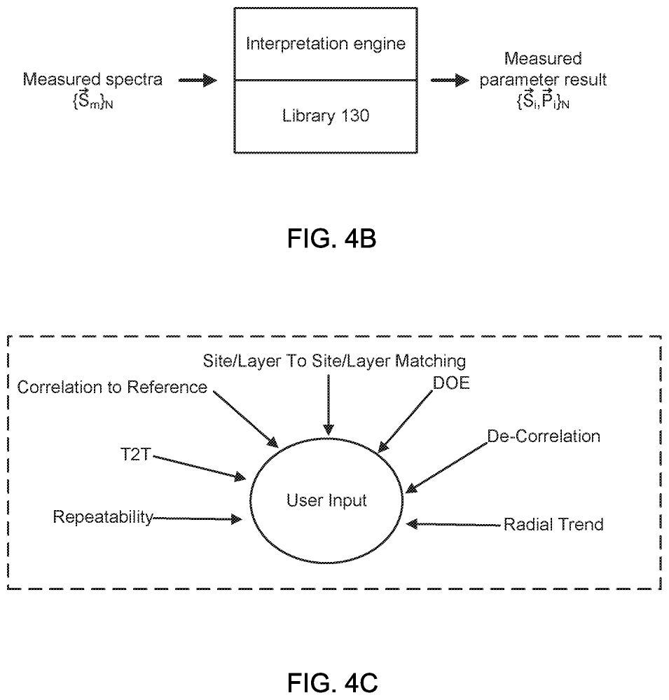

Reference is made to FIGS. 4A-4C summarizing the technique of the present invention as described in more details above. As shown in FIG. 4A, the library estimator 112 together with its associated interpretation engine 114 (after being trained and tested in the conventional manner to prepare the preliminary/initial library) undergo the optimization procedure. To this end, the preliminary measured data {\vec{S}ₘ}_{N} is input and after being interpreted by iterative fitting procedure, the measured parameter results {\vec{S}ᵢ, \vec{P}ᵢ}_{N} are generated. This data is then analyzed by the merits evaluator 116 taking into account the user input (i.e. QOR condition(s) defining the required merits), and the calculated merits are ranked (e.g. by determining the sum of the merits) and the iterative procedure is repeated by modifying the library convergence criteria until obtaining the minimal rank. The inventors have shown that such optimization procedure is very fast, i.e. a few minutes per run.

Upon completing the accomplishing of the optimized library 130 with its interpretation engine, it can be used in online automatic measurement/inspection process on structure to process/interpret real-time measured data. As shown in FIG. 4B, a library interpretation engine of the optimized library 130) receives measure data {\vec{S}ₘ}_{N} (which is real data and not the preliminary one, although the same indication is used) and the library responds by measured parameter result {\vec{S}ᵢ, \vec{P}ᵢ}_{N} obtained by performing typical fitting procedure while applied to the optimized library data. By this both criteria are satisfied, i.e. best fit criteria and quality of results criteria defined by user. Also, as will be exemplified further below, the ambiguity of solution is improved. Examples of such quality of results conditions typically required in the semiconductor industry are illustrated in FIG. 4C.

In order to demonstrate the advantages of the present invention, the following should be considered. The conventional approach of library creation as described above with reference to FIGS. 1A-1E does not allow automatic and robust adjustment of the measured data interpretation to additional user's requirement with regards to the quality of results, while providing required accuracy. Such additional requirements at user side are dictated by a need for tight process control and highly accurate OCD metrology to meet the requirements of stabilization of the manufacturing process and yield optimization.

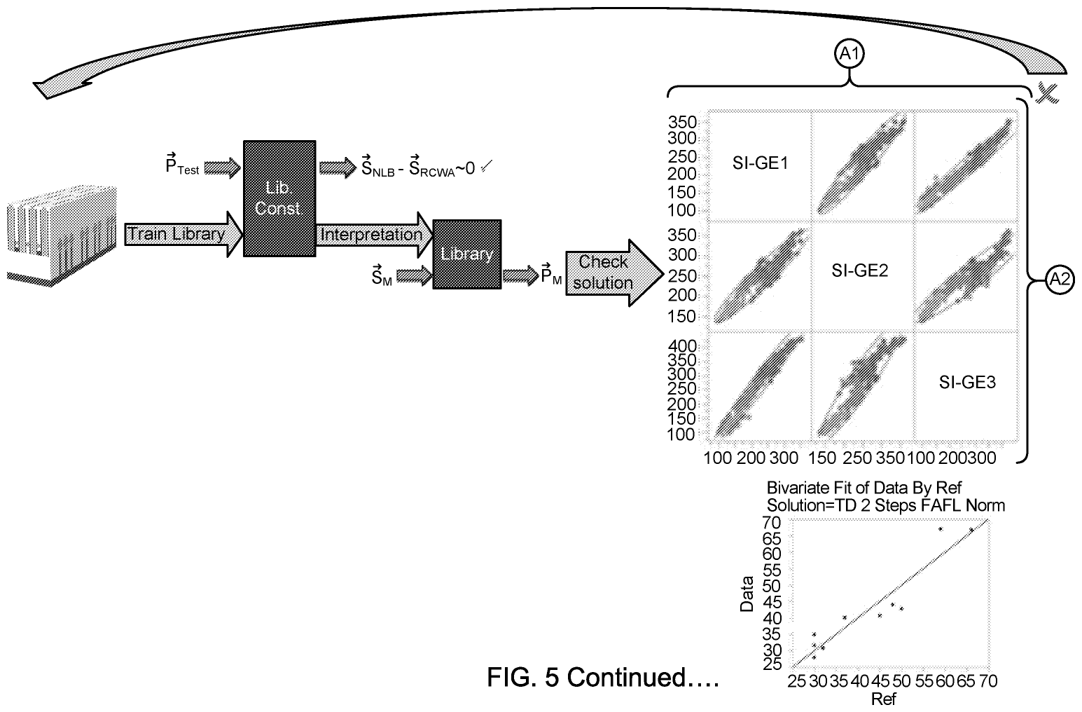

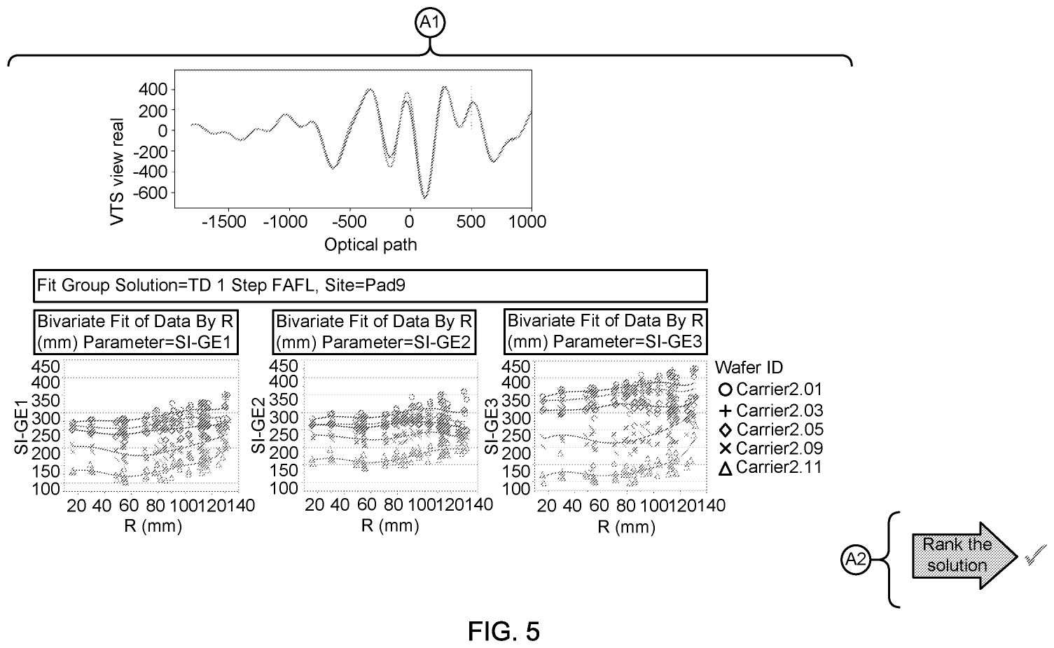

Reference is made to FIG. 5 schematically illustrating a complex and inefficient and thus impractical solution flow to incorporate the additional user input requirements in the library adaptation using the conventional approach. Similar to the flow scheme described in FIGS. 1A to 1B, the library constructor is trained and tested with testing parameter set \vec{P}_{Test} to achieve predetermined library conversion criteria. During the online use of the trained library, experimental spectra \vec{S}_{M} are input into the trained library interpretation engine, resulting in the parameter set \vec{P}_{M} corresponding to the measured spectra \vec{S}_{M}. In order to consider additional user's requirement associated with the required quality of results, the solution (i.e., the parameters \vec{P}_{M}) has to be checked/verified for various additional merits, including, for example, global wafer merits (e.g., tool-to-tool etc.) and local die merits (e.g., spectral fit, match to reference, etc.), listed in Table 1.

TABLE 1

| | Manufacturing | Customer | External tool | Model |
|---|---|---|---|---|
| Tool merits | process merits | tool merits | data | merits |
| Tool To | Parameter's | Parameter | Match to | Spectral |
| Tool | correlation/non- | radial trend | reference (R², | fit |
| | correlation | | Slope, Offset) | |
| Repeatability | Site/Layer to | Within wafer | | |
| | Site/Layer | parameter | | |
| | correlation | range | | |
| | Wafers skew | | | |
| | (DOE) | | | |

Solution rank is calculated, being implemented, for example, by the sum of merits, R(\vec{P})=ΣMeritᵢ, which is a sum of all labeled (floating) and unlabeled (fixed) external reference and is a measure of the goodness of the solution. If the solution rank complies with the pre-determined specification (typically, minimum value), the output parameters \vec{P}_{M} are accepted as the solution. If the solution rank is out of specification, the model needs to be revised and the library estimator needs to be reconstructed. However, this must be done manually, i.e., such manual scheme is targeted to optimize the solution. However, given a very tight time frame during current manufacturing processes of high-end applications, such trial-and-error library optimization process cannot keep the pace.

The inventors recognized this need in library optimization and developed the above-described novel approach for automatic library optimization carried out offline and once for specific model or set of models and specific user input regarding one or more quality of results conditions. The quality of results is evaluated using merits defined by the user, which are combined to a total rank. The optimized library can then be used for interpretation of new spectra, not included in the original data used for its construction.

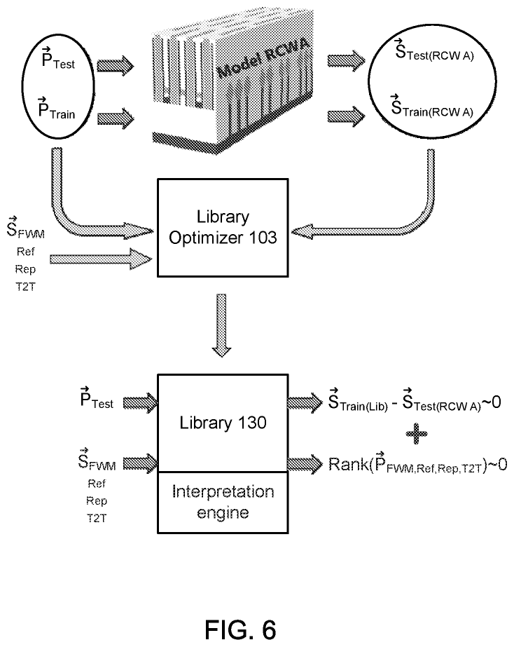

The above-described approach of the invention for the optimized library creation is shown as a top-level flow diagram in FIG. 6 in a self-explanatory manner. As shown, after training and testing steps the library estimator is optimized using interpretation of predetermined measured data prepared in accordance with user input. Such measured data is illustrated in the figure as:

$${\vec{S}}_{{{{FWM}_{Ref}}_{Rep}}_{T 2 T}}$$

where the indexes correspond to merits of, respectively, full wafer map (FWM), correlation to reference (Ref), repeatability (Rep) and tool-to-tool matching (T2T). are provided at the library construction stage. The process proceeds as described above with reference to FIGS. 2 and 3, until the optimized library is created which meets both of the following two criteria: best fit criteria ((\vec{S}_{Test(Lib)}−\vec{S}_{Test(RCWA)})˜0) and quality of results criteria, i.e. minimal rank of the required merits (Rank(\vec{P}_{FWM,Ref,Rep,T2T})˜0). When both criteria (model fit and minimum rank) are achieved, the iterative process is stopped, and the optimized library can be used online for interpretation of new measured data (spectra).

It should be noted that the optimized library of the invention is still a model-based library, therefore the condition where bad spectral fit is obtained but minimal rank is achieved is not allowed, i.e., the convergence conditions on the spectral fit may be modified and somewhat relieved in order to achieve a minimal rank, but the Optimized Library is still a model-based library and spectral fit is always required.

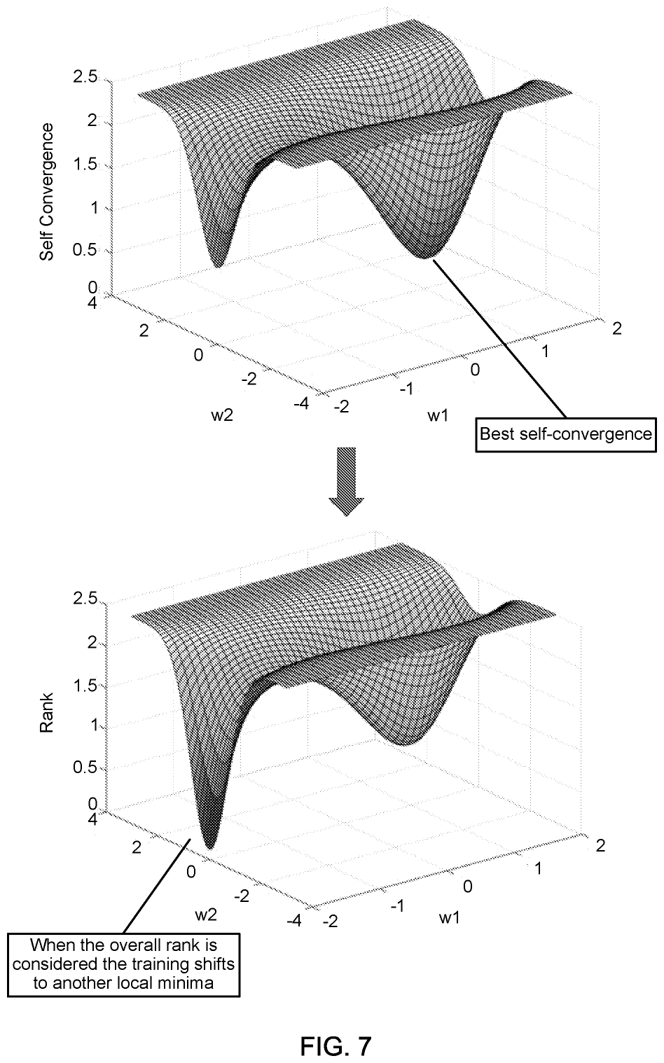

As was already mentioned above, building the library using conventional approach frequently results in several minima which reflects the fact that several spectra (i.e., several parameters' sets) may match the same convergence conditions. The present invention provides improvement in this respect as well. In this connection reference is made to FIG. 7. As shown in the figure, the best fit criteria result (best self-convergence of the library) provides two minima, i.e., two solutions thus suffering from ambiguity. Further optimization of the library according to the invention, as described above, by considering the overall rank for the required merits, i.e., properly modifying the library convergence criteria, the library training is shifted to another local minima which may represent a better fitting model to the broader set of constraints.

As already described above, with reference to FIGS. 2 and 3, the optimized library of the invention uses an optimizable interpretation engine 114, i.e., it has internal degrees of freedom which allow changing its interpretation results. For any measured data piece (spectrum) it returns corresponding parameters' values and a theoretical data (spectrum), while best fit between the measured and theoretical data is one of the criteria used to determine the results (i.e., the parameters). Yet, since it has internal degrees of freedom, additional input data relating to required quality of results for the available measured data can be used (via the merits and the combined rank) in addition to (e.g., during interpretation of new measured data) spectral fit to obtain the best interpretation scheme. After optimization on available data, such interpretation engine 114 can be used as part of the library management system 130 to operate together with the library estimator 112 to interpret new measured spectra.

The new optimizable interpretation engine of the invention is described above with reference to FIG. 4A. The following is a specific example of the operation of the optimizable interpretation engine 114.

The optimizable interpretation engine 114 utilizes a set of theoretical spectra

$${\{ {S}_{i} ( {\vec{P}}_{i} ) , {\vec{P}}_{i} \}}_{i = 1}^{N}$$

calculated from the model at random points in the parameter space. For given measured data {\vec{S}ₘ}_{N}, corresponding parameter values are estimated in the following way:

$${\vec{P}}_{m} = \sum {w}_{i}^{m} {\vec{P}}_{i} ; {\vec{w}}_{i}^{m} = {min ( \sum {w}_{i} {\vec{S}}_{i} - {\vec{S}}_{m} )}^{2} \qquad ( 1 )$$

where \vec{S}ᵢ and \vec{P}ᵢ are, respectively, the theoretical spectra and parameters corresponding to the measured spectrum \vec{S}ₘ, and

$${\vec{w}}_{i}^{m}$$

is the vector of weights minimizing the merit between the chosen set of theoretical spectra and the measured spectrum.

Interpretation (i.e., selection of the weights

$${\vec{w}}_{i}^{m} )$$

is performed by some interpolation of N theoretical spectra (for example, using eq. (1) above). The internal degree of freedom of the interpretation algorithm is the selection of a subset from the original N theoretical spectra used in the interpolation, where different subsets of the N spectra may give different interpretation results.

The above specific example of the technique of the invention to find the solution, i.e., the theoretical spectra and parameters that give the best fit to the measured spectrum, may be formulated in a general (mathematic) form.

The optimizable interpretation engine of the invention provides for selection of a function of theoretical spectrum (for example the sum Σwᵢ\vec{S_{ι}} in Eq. (1) above, which typically uses only part of the theoretical spectra in the sum) from a parameterized family of functions, so that the selected function optimally predicts the values of geometrical and/or material parameters of a structure (pattern on wafer), for a given measured spectrum.

For example, let us consider h_{θ}(S) as the selected function of theoretical spectrum. This function may be represented by the weighted sum of N theoretical spectra (selected subset):

$${h}_{θ} ( S ) = \sum {w}_{i}^{m} {\vec{P}}_{i}$$

where θ is the chosen subset and wₘⁱ are the chosen weights from the condition

$${\vec{w}}_{i}^{m} = {min ( \sum {w}_{i} {\vec{S}}_{i} - {\vec{S}}_{m} )}^{2}$$

of Eq. (1). The mathematical description of the interpretation method is:

$$Find θ , so {h}_{θ} ( S ) = P gives an optimal parameter prediction .$$

Selection of the appropriate subset of N spectra and of the corresponding function h_{θ}(S) is performed while optimizing the quality of results for the available measured data, as evaluated by the rank/combined rank (for all the merits, where the number of merits may be 1 or more, as per user's input) calculated from the parameter results. The interpretation method may involve minimization of the rank (loss function), which is formed by the merit(s), over the space of parameters of the family of functions.

Mathematical description may be as follows: Find optimal θ by minimizing loss function L=ΣᵢMᵢ(h_{θ}), wherein Mᵢ are the merits (i≥1) of results which are based on user input and are thus included in the rank calculation (e.g., those appearing in Table 1). In the following, some non-limiting examples of the merits are described:

One merit can be the degree to which the function h_{θ} predicts correctly the geometrical/materials parameters for given multiple representative theoretical spectra, generated from a model by solving Maxwell's equations. Different theoretical spectra have different weights in the merit, and the weights belong to the set of parameters being optimized by the interpretation method. These weights may be continuous or discrete (e.g., 0's and 1's). Mathematical description is as follows: The first merit can be:

$${M}_{1} = {\sum }_{{S}_{t}} ρ ( {S}_{t} ) {‖ {h}_{θ} ( {S}_{t} ) - {P}_{t} ‖}^{2} ,$$

where Sₜ is a representative set of theoretical spectra that correspond to the parameters Pₜ. The weights ρ(Sₜ) can be continuous or discrete (or even binary) and are optimized together with the parameters θ.

A second merit can be the degree to which the prediction agrees with measured geometrical/material parameters (reference) for a certain set of measured spectra. The reference parameters may be obtained from a different metrology. Mathematical description is as follows: The second merit can be

$${M}_{2} = {\sum }_{{S}_{ref}} {‖ {h}_{θ} ( {S}_{ref} ) - {P}_{ref} ‖}^{2} ,$$

where S_{ref} are measured spectra that correspond to available reference parameters P_{ref}.

A third merit may be the degree of smoothness of predicted geometrical/material parameters across a wafer or several wafers.

A fourth merit may be a mathematical formula that describes the degree to which a wafer-level signature (spectral signature) of one or several geometrical/material parameters has a radial nature.

A fifth merit may be the degree to which repeatability spectra predict similar geometrical/material parameter values.

A sixth merit may be the degree to which spectra from the same structure measured on different tools predict similar geometrical/material parameter values.

A seventh merit may be the degree to which the prediction of geometrical/material parameters agrees with a Design-of-experiment (DOE) generated by the customer.

AN eighth merit may be the degree to which the predictions of geometrical/material parameters is stable to process variations, as reflected from measurements of additional wafers.

A ninth merit may the degree to which the predictions of geometrical/material parameters is insensitive to model errors (e.g., fixed parameter noise).

The technique of selection of the function from the parameterized family of functions may utilize any choice and any number of merits with any set of weights, depending on the data available.

In some examples, the optimizable interpretation engine of the present invention may be configured as a linear interpretation engine. The engine uses a set of theoretical spectra calculated from the model at random points in the parameter space

$${\{ {S}_{i} ( {\vec{P}}_{i} ) , {\vec{P}}_{i} \}}_{i = 1}^{N}$$

and interpretation is performed by a linear interpolation in the parameter space and the spectral space: \vec{S}_{T}=Σwᵢ\vec{S_{ι}}; \vec{P}_{T}=Σwᵢ\vec{P_{ι}}, where the coefficients wᵢ depend on the interpreted measured spectrum and the theoretical spectra, e.g., fulfilling the condition of Eq. (1).

Once the interpretation engine has been optimized for the specific application (i.e. specific user input/QOR defining the merit(s)) based on selected/preliminary measured data, it can be used as part of the library to interpret new measured data, as described above.

1. A computer system configured and operable as a library constructor for use in extracting one or more parameters of a patterned structure from real time measured data obtained on said structure, the computer system comprising:
data input utility for receiving input data comprising preliminary measured data obtained from at least a part of a structure, and comprising data indicative of user-defined quality of measurement results (QOR); and
a data processor configured and operable for processing and analyzing the input data and predetermined theoretical modeled data corresponding to said measured data to modify said theoretical modeled data and define optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured.

2. The computer system according to claim 1, wherein said data processor comprises a library optimizer utility configured and operable to provide the theoretical modeled data satisfying the first condition and apply a modification procedure to said theoretical modeled data by iterative training and testing it on the preliminary measured data in accordance with one or more merits determined by said data indicative of the user-defined QOR, until said one or more merits satisfy a predetermined ranking, to thereby obtain the optimized theoretical data.

3. The computer system according to claim 2, wherein the library optimizer utility is configured to generate said theoretical modeled data satisfying the first condition by applying iterative training, testing and validation procedures to at least one predetermined model using train and test parameters of the structure.

4. The computer system according to claim 2, wherein the library optimizer utility comprises:
a library estimator having library convergence criteria with respect to model data;
an interpretation engine associated with said library estimator and being configured and operable to interpret input measured data and operate together with said library estimator to perform iterative data interpretation to provide interpretation results enabling to identify theoretical modeled data matching said input measured data, wherein said interpretation engine has internal degrees of freedom for modifying the interpretation results by interpreting both the preliminary measured data and the QOR, enabling to determine a theoretical data set formed by matching theoretical data and corresponding theoretical values for a set of structure parameters;
a merits evaluator utility configured and operable to analyze a quality of results represented by said set of parameters with respect to said QOR and generate data indicative of corresponding at least one merit;
a ranking utility configured and operable to rank said data indicative of the at least one merit and, upon identifying that the rank does not satisfy said second condition, initiate operation of the interpretation engine and the library estimator with modified library convergence criteria to perform the iterative data interpretation procedure by modifying the matching theoretical data until it satisfies the second condition.

5. The computer system according to claim 1, wherein said data indicative of the user-defined QOR comprises at least one of the following: repeatability of measurement for at least one parameter; correlation of at least one parameter of the structure to reference, tool-to-tool (T2T) variation in measurement, radial trend, de-correlation of parameters, site/layer-to-site/layer matching, Design-of-experiment (DOE).

6. The computer system according to claim 1, wherein said measured data is optical data.

7. The computer system according to claim 6, wherein the measured data comprises spectral data.

8. The computer system according to claim 7, wherein said data indicative of the user-defined QOR comprises a degree to which the theoretical modeled data predicts at least one of geometrical and material-relating parameters of the structure, for different theoretical spectra.

9. The computer system according to claim 1, wherein said data indicative of the user-defined QOR comprises degree of smoothness of at least one of geometrical and material-related parameters across the same structure or within several structures.

10. A computer system configured and operable as a library constructor for use in extracting one or more parameters of a patterned structure from real time measured data obtained on said structure, the computer system comprising:
data input utility for receiving input data comprising preliminary measured data obtained from at least a part of a structure, and comprising data indicative of user-defined quality of measurement results (QOR); and
a data processor configured and operable for processing and analyzing the input data and predetermined theoretical modeled data and define optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured, the data processor comprising:
a library optimizer utility configured and operable to provide the theoretical modeled data satisfying the first condition and apply a modification procedure to said theoretical modeled data and obtain the optimized theoretical data;
a merits evaluator utility configured and operable to analyze a quality of results represented by said set of parameters with respect to said QOR and generate data indicative of corresponding at least one merit; and
a ranking utility configured and operable to rank said data indicative of the at least one merit and selectively initiate the iterative data interpretation procedure by modifying the matching theoretical data until it satisfies the second condition.

11. A computer system configured and operable as a library constructor for use in extracting one or more parameters of a patterned structure from real time measured data obtained on said structure, the computer system comprising:
data input utility for receiving input data comprising: preliminary measured data obtained from at least a part of a structure; and comprising data indicative of user-defined quality of measurement results (QOR) comprising a degree to which predetermined theoretical modeled data predicts at least one of geometrical and material-relating parameters of the structure for different theoretical spectra; and
a data processor configured and operable for processing and analyzing the input data and the predetermined theoretical modeled data corresponding to said measured data to modify said theoretical modeled data and define optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured.

12. A data processing method for extracting one or more parameters of a patterned structure from real time measured data obtained on said structure, the method comprising:
receiving input data comprising preliminary measured data obtained from at least a part of a structure, and data indicative of user-defined quality of measurement results (QOR); and
processing and analyzing the input data and predetermined theoretical modeled data corresponding to said measured data to modify said theoretical modeled data and define optimized theoretical data enabling extraction therefrom, in response to the preliminary measured data, one or more parameters of the structure satisfying a first condition of best fit criteria between the optimized theoretical data and the preliminary measured data, and a second condition of said QOR, thereby enabling further use of said library for interpretation of the real-time measured data to extract the one or more parameters of the structure being measured.

13. The method according to claim 12, wherein said processing comprising: providing the theoretical modeled data satisfying the first condition; and applying a modification procedure to said theoretical modeled data by iterative training and testing it on the preliminary measured data in accordance with one or more merits determined by said data indicative of the user-defined QOR, until said one or more merits satisfy a predetermined ranking, to thereby obtain the optimized theoretical data.

14. The method according to claim 13, wherein said providing of the theoretical modeled data satisfying the first condition comprises generating said theoretical modeled data satisfying the first condition by applying iterative training, testing and validation procedures to at least one predetermined model using train and test parameters of the structure.

15. The method according to claim 13, wherein providing of the theoretical modeled data satisfying the first condition comprises:
providing a library estimator having a library convergence criteria with respect to model data; and an interpretation engine associated with said library estimator, said interpretation engine being configured and operable to interpret input measured data and operate together with said library estimator to perform iterative data interpretation to provide interpretation results enabling to identify theoretical modeled data matching said input measured data, wherein said interpretation engine has internal degrees of freedom for modifying the interpretation results by interpreting both the preliminary measured data and the QOR, enabling to determine a theoretical data set formed by matching theoretical data and corresponding theoretical values for a set of structure parameters;
analyzing a quality of results represented by said set of parameters with respect to said QOR and generating data indicative of corresponding at least one merit;
ranking said data indicative of the at least one merit and, upon identifying that the rank does not satisfy said second condition, initiating operation of the interpretation engine and the library estimator with modified library convergence criteria to perform the iterative data interpretation procedure by modifying the theoretical matching data until it satisfies the second condition.

16. The method according to claim 12, wherein said data indicative of the user-defined QOR comprises at least one of the following: repeatability of measurement for at least one parameter; correlation of at least one parameter of the structure to reference, tool-to-tool (T2T) variation in measurement, radial trend, de-correlation of parameters, site/layer-to-site/layer matching, Design-of-experiment (DOE).

17. The method according to claim 12, wherein said measured data is optical data.

18. The method according to claim 17, wherein the measured data comprises spectral data.

19. The method according to claim 18, wherein said data indicative of the user-defined QOR comprises a degree to which the theoretical modeled data predicts at least one of geometrical and material-relating parameters of the structure, for different theoretical spectra.

20. The method according to claim 12, wherein said data indicative of the user-defined QOR comprises degree of smoothness of at least one of geometrical and material-related parameters across the same structure or within several structures.
